(19) United States
(12) Patent Application Publication
(10) Pub. No.: US 2004/0095798 A1
(43) Pub. Date: May 20, 2004

(54) Ferroelectric memory architecture

(76) Inventors: Joerg Wohlfahrt, Kanagawa (JP); Michael Jacob, Kanagawa (JP); Thomas Roehr, Kanagawa (JP)

Correspondence Address: HORIZON IP PTE LTD, 166 Kallang Way, 6th Floor, SINGAPORE 349249, SG

(21) Appl. No.: 10/065,125

(22) Filed: Sep. 19, 2002

(51) Int. Cl. G11C 11/22

(52) U.S. Cl. 365/145

(57) ABSTRACT

An improved architecture which reduces the adverse impact of the disturb pulse on non-selected ferroelectric memory cells is disclosed. The architecture provides plateline selection switches for selectively coupling memory groups on the selected side of the memory block to the plateline and decoupling the non-selected side of the memory block from the plateline. By decoupling the non-selected side of the memory block from the plateline, the plate pulse does not adversely affect the memory cells in the non-selected side of the memory block.

### BACKGROUND OF INVENTION

Ferroelectric metal oxide ceramic materials such as lead zirconate titanate (PZT) have been investigated for use in ferroelectric semiconductor memory devices. Other ferroelectric materials including strontium bismuth tantalate(SBT) can also be used. FIG. 1 shows a ferroelectric memory cell with a transistor 142 and a capacitor 144. The capacitor comprises a ferroelectric metal ceramic layer 190 sandwiched between first and second electrodes 192 and 193. The electrodes typically are formed from a noble metal such as platinum. Other conductive materials or conductive oxides, such as strontium ruthenium oxide (SRO) or iridium oxide (IrO), are also useful. Electrode 192 is coupled to a plateline (not shown) and electrode 193 is coupled to the transistor, which selectively couples or decouples the capacitor from a bitline (not shown), depending on the state of a wordline (not shown) coupled to a gate of the transistor.

The capacitor uses the hysteresis polarization characteristic of the ferroelectric material for storing information. The logic value stored in the memory cell depends on the polarization of the capacitor. To change the polarization a voltage, which is greater than the switching voltage (coercive voltage) needs to be applied across the capacitor's electrodes. The polarization of the capacitor depends on the polarity of the voltage applied. An advantage of the ferroelectric capacitor is that it retains its polarization state after power is removed, resulting in a non-volatile memory cell.

Referring to FIG. 2, a pair of bitlines (bitline BL and bitline complement/BL) is shown. Each of the bitlines includes first (e.g., left)and second (e.g., right) groups of memory cells 110a-b or 110c-d. The memory cells of a group, each with a transistor 142 coupled to a capacitor in parallel, are coupled in series. Such memory architectures are described in, for example, Takashima et al., “High Density Chain ferroelectric random access Memory (chain FRAM)”, IEEE Jrnl. of Solid State Circuits, vol.33, pp.787-792, May 1998, which is herein incorporated by reference for all purposes. A sense amplifier is coupled to the bitlines to facilitate access to the memory cell.The gates of the cell transistors can be gate conductors which are coupled to or serve as wordlines. A selection transistor 130 is provided to selectively couple one end of the group to its respective bitline (e.g., 130a couples group 110a to BL; 130b couples group 110b to BL; 130c couples group 110c to/BL; and 130d couples group to/BL). A plateline is coupled to the other end of the group (e.g., PL or/PL). The groups on the left and right side on the same bitline share the same plateline (e.g., groups on BL are coupled to PL and groups on/BL are coupled to/PL). Numerous bitline pairs are addressed via wordlines to form a memory block.

The selection transistors are controlled by different bitline select (BS) control signals. For example, BS0 and BS2 respectively control selection transistors 130a and 130b to selectively couple or decouple memory groups 110a and 110b to BL; BS1 and BS3 respectively control selection transistors 130c and 130d to selectively couple or decouple memory groups 110c and 110d to/BL. During a memory access, one cell is selected from one of the bitline pair by selecting one of the wordlines (e.g., one of the wordlines WL₀-WL₁₅ is selected). Depending on which group the cell is located, the corresponding BS signal is activated. For a group on the left side of the platelines, BS0 or BS1 is activated depending on whether the group is coupled to BL or/BL. Otherwise, BS2 or BS3 is activated to couple a group located on the right side of the platelines.

An access plate pulse, for example, about 2.5V is provided on either PL or/PL, depending on whether the selected cell is located on BL or/BL, after the appropriate bitline select signal is activated. This pulse creates an electric field across the capacitor of the selected cell, which is sensed by the sense amplifier. However, with respect to the non-selected cells of the non-selected group on the other side of the platelines, this pulse acts as a disturb pulse, which can have a negative effect on the polarization of the capacitors of the non-selected. For example, due to coupling mechanism and leakage of transistors, the capacitors of the non-selected cells on the other side of the platelines see a small plate pulse. This pulse causes an inelastic travel of the polarization along the hysteresis curve, slowly decreasing the remnant polarization of the ferroelectric material. As a result, read signal strength is decreased, adversely affecting reliability and service life of the device.

From the foregoing discussion, it is desirable to provide an improved ferroelectric memory architecture which decreases the negative effects of the disturb pulse.

### SUMMARY OF INVENTION

The invention relates to integrated circuits (ICs) in general, and more particularly to ferroelectric memory ICs having a series architecture. In one embodiment, the IC includes first and second bitlines which form a bitline pair. The first bitline includes first and second memory groups and the second bitline includes third and fourth memory groups. A memory group comprises first and second ends with a plurality of memory cells serially coupled between the ends. A first end of a memory group is provided with a bitline selection switch for selectively coupling the memory group to its respective bitline. The first and third memory groups form one section of the bitline pair and the second and fourth groups form a second section of the bitline pair.

Plateline selection switches are provided at the second ends of the first and second memory groups to selectively couple the groups to a first plateline. In one embodiment, plateline selection switches are provided at the second ends of the third and fourth memory groups to selectively couple the groups to a second plateline. By providing plateline selection switches for the memory groups, the plate pulse is experienced by the section of the bitline in which the selected memory cell is located. The non-selected section is isolated from the pulse due to the plateline switches. This reduces the adverse affects of the disturb pulse on memory cells in the non-selected section of the bitline pair.

### BRIEF DESCRIPTION OF DRAWINGS

FIG. 1 shows a conventional ferroelectric capacitor;

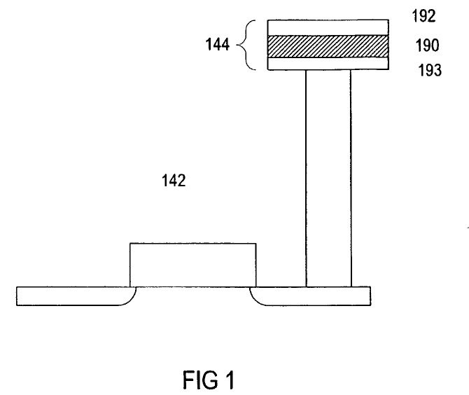

FIG. 2 shows a bitline pair of a ferroelectric memory block with grouped architecture;

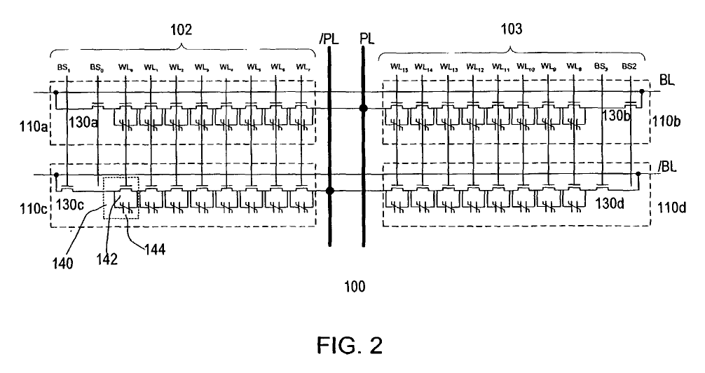

FIG. 3 shows an embodiment of the invention; and

FIG. 4 shows a cross-sectional view of one embodiment of the invention.

### DETAILED DESCRIPTION

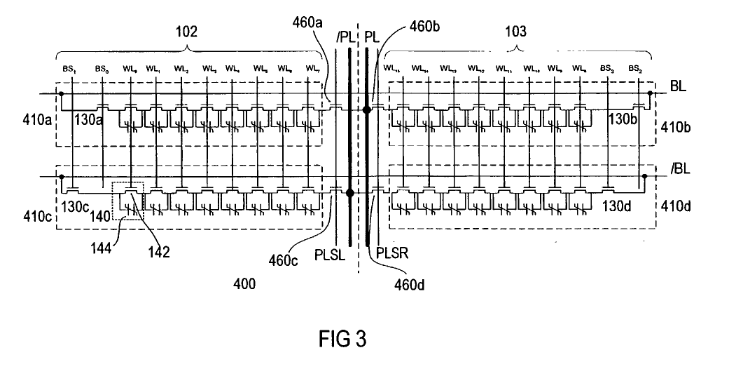

Referring to FIG. 3, a bitline pair comprising first and second bitlines BL and/BL, each including first and second groups (410a-b or 410c-d) of memory cells 140, is shown. In one embodiment, a group comprises 8 memory cells coupled in series. Groups having other number of memory cells are also useful. Preferably, the number of cells within a group is equal to 2^{y}, where y is equal to a whole number≧1. A memory cell includes a transistor 142 coupled to a capacitor 144 in parallel. The transistor, for example is an n-FET and the capacitor is a stacked capacitor. Other types of transistors (e.g. p-FETs) or capacitors (e.g., trench) are also useful. Coupling a memory group to its respective bitline is a selection transistor 130. A first plateline PL is commonly coupled to the first and second memory groups of BL; a second plateline/PL is commonly coupled to the first and second memory groups of/BL.

A plurality of bitline pairs can be interconnected via wordlines to form a memory block. For example, the gates of the cell transistors can be gate conductors, which are coupled to or serve as wordlines. The memory block is separated into first (left) and second (right) sections 102 and 103, each comprising a group of bitline. As shown, wordlines WL₀ to WL₇ and bitline select signals BS0 and BS1 are used to address memory groups in the first section and wordlines WL₈ to WL₁₅ and BS2 to BS3 are used to address memory groups on the second section.

In accordance with the invention, only the memory groups in the section (either the left or right) in which the selected memory cell is located are coupled to the respective platelines PL and/PL. For example, if the decoded row address of the memory access is equal to one of the wordlines WL₀ to WL₇, the memory groups in the first section are coupled to the platelines. On the other hand, the memory groups in the second section are coupled to the platelines if the decoded address is equal to one of the wordlines WL₈ to WL₁₅.

In one embodiment, a section selection (SS) transistor 460 is provided between the end of a memory group and a plateline (either PL or/PL), enabling the memory group to be selectively coupled or decoupled to the plateline. The SS transistors, for example, are n-FETs. Other types of transistors, such as p-FETs are also useful. In one embodiment, a first section select signal PLSL controls the SS transistors coupled to memory groups in the first section and a second section select signal PLSR controls the SS transistors coupled to the memory groups in the second section.

During a memory access to a memory cell in the first section, an active PLSL (e.g., logic 1) and inactive PLSR (e.g., logic 0) are provided to couple the memory groups in the first section to and decoupling the memory groups in the second section from the platelines. For a memory access to a memory cell in the second section, an inactive PLSL and active PLSR is provided.

The PLSL and PLSR signals can be normally active or normally inactive. If normally active, the selection signal of the non-selected side should be deactivated prior to the generation of the access pulse. If normally inactive, the selection signal for the selected side should be activated prior to the generation of the access pulse. Through the use of SS transistors the access pulse is not seen by memory cells in the non-selected section of the block. This reduces the adverse effects of the access pulse on memory cells in the non-selected section of the memory block. Additionally, reducing the number of cells coupled to the plateline advantageously enables smaller plateline drivers (space reduction) as well as lower power consumption since the capacitive load is reduced by about half.

In one embodiment of the invention, the selection transistors are controlled by different control signals. The four groups of the bitline pair, as illustrated, are each controlled by a different control signal. For example, BS0 and BS2 respectively control selection transistors 130a and 130b to selectively couple one of the groups 410a or 410b to BL. Likewise, BS1 and BS3 respectively control selection transistors 130c and 130d to selectively couple one of the groups 110c or 110d to/BL. Providing common bitline select signals to control the selection transistors of the groups coupled to the same bitline can also be useful.

When different bitline selectsignals are used for each group, the PLSL and PLSR signals can be derived from the bitline select signals. In one embodiment, an active PLSR signal is derived from either an active BS2 or BS3 (e.g., PLSR=(BS2 U BS3)) and an active PLSL signal is derived from either an active BS0 or BS1 (e.g., PLSL=(BS0 U BS1)).

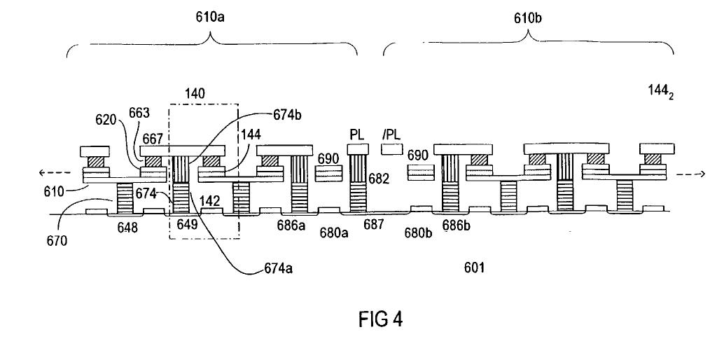

FIG. 4 shows a cross-sectional view of portions of two ferroelectric memory groups 610a-b that are couple to a bitline in accordance with one embodiment of the invention. As shown, the groups are formed on a semiconductor substrate 601, such as silicon. Other types of semiconductor substrates can also be used. The memory group comprises, for example, 8 memory cells 140. Memory groups of other sizes are also useful. Preferably, the number of cells within a group is equal to 2^{y} where y is a whole number≧1. More preferably, y is from 2 to 5. A memory cell comprises a transistor 142 coupled to a ferroelectric capacitor 144. The transistors are coupled to wordlines.

In one embodiment, the transistors of the memory cells within the group share a diffusion region. Sharing of the diffusion region advantageously reduces surface area required. The capacitors of adjacent memory cells are interconnected. As shown, two adjacent capacitors share a common electrode 610 to form a capacitor pair. Two non-common electrodes 620 of adjacent capacitors from adjacent capacitor pairs are coupled to a coupling interconnect 667 via studs 663. Preferably, the common electrode is the lower electrode while the non-common electrode is the upper electrode. A first common diffusion region 648 of a memory cell transistor is coupled to the common electrode of a capacitor pair via a contact stud 670 and the coupling interconnect is coupled to a second common diffusion region 649 via contact stud 674.

The memory groups are coupled to a plateline (either PL or/PL) at first adjacent ends of the memory group via respective SS transistors 680a-b. Illustratively, the memory groups are coupled to PL. The PLSL signal line is coupled to the gate of, for example, SS transistor 680a while the PLSR signal line is coupled to SS transistor 680b. Based on which section is selected, one of the groups is coupled to the PL via the SS transistor. In one embodiment, the SS transistors of the two memory groups share a common diffusion region 687 which is coupled to PL via contact stud 682 while the other diffusion region of the SS transistors is shared with a cell transistor. In one embodiment, the SS transistor is located in an area between the last cell transistor and plateline. This area, for example, is occupied by dummy capacitors 690. By placing the SS transistors in the area already occupied by the dummy capacitors advantageously enables the invention to be implemented without the need of additional chip area or reducing the need for additional chip area.

Illustratively, the taller contacts (e.g., contacts 674) are formed in two process steps. Other schemes can also be used to form the different types of studs. The first step forms lower portion (e.g., 674a) along with the studs 470. The second process step forms the upper portion (e.g., 674b). Such studs can also be formed using a single process step. Additional structures (not shown) such as support logic, passivation layers, and package may be included to complete the IC.

While the invention has been particularly shown and described with reference to various embodiments, it will be recognized by those skilled in the art that modifications and changes may be made to the present invention without departing from the spirit and scope thereof. The scope of the invention should therefore be determined not with reference to the above description but with reference to the appended claims along with their full scope of equivalents.

1. an integrated circuit (IC) comprising:
a plurality of memory cells coupled in series to form a first memory group, wherein a memory cell comprises a capacitor coupled to a cell transistor;
a bitline coupled to a first end of the group; and
a first section switch is coupled to a second end of the group and a plateline, the section switch, when activated, selectively couples the plateline to the group.

2. The integrated circuit of claim 1 wherein the first section switch is activated to couple the group to the plateline when the group is selected and deactivated to decouple the plateline from the group when the group is not selected.

3. The integrated circuit of claim 1 further comprises:
a second memory group having a first end coupled to the bitline; and
a second section switch coupled to a second end of the second memory group and the plateline, the second section switch selectively coupling the second memory group to the plateline.

4. The integrated circuit of claim 3 wherein:
the first section switch is activated to couple the first memory group to the plateline when the memory group is selected and deactivated to decouple the plateline from the memory group when the memory group is not selected; and
the second section switch is activated to couple the second group to the plateline when the second group is selected and deactivated to decouple the plateline from the second group when the second group is not selected.

5. The integrated circuit of claim 3 wherein the first group is part of a first section of a memory array and the second group is part of a second section of the memory array.

6. The integrated circuit of claim 5 wherein:
the first section switch is activated to couple the first memory group to the plateline when the memory group is selected and deactivated to decouple the plateline from the memory group when the memory group is not selected; and
the second section switch is activated to couple the second group to the plateline when the second group is selected and deactivated to decouple the plateline from the second group when the second group is not selected.

7. The integrated circuit of claim 3 further comprises:
a complement bitline;
a first complement memory group having its first end coupled to the complement bitline;
a first complement section switch coupled to the plateline and a second end of the first complement memory group, the first complement section switch selectively coupling the first complement memory group to the plateline;
a second complement memory group having its first end coupled to the complement bitline; and
a second complement section switch coupled to the plateline and a second end of the first complement memory group, the first complement section switch selectively coupling the first complement memory group to the plateline.

8. The integrated circuit of claim 7 wherein the first section switch and first complement section switch are controlled by a first section selection signal and the second section switch and second complement section switch are controlled by a second section selection signal.

9. The integrated circuit of claim 7 wherein the first memory group and first complement memory group are part of a first section of a memory array and the second memory group and second complement memory group are part of a second section of the memory array.

10. The integrated circuit of claim 9 wherein the first complement section switch is activated to couple the first complement memory group to the plateline when the first complement memory group is selected and deactivated to decouple the plateline from the first complement memory group when the first complement memory group is not selected.

11. The integrated circuit of claim 3 further comprises:
a complement bitline;
a first complement memory group having its first end coupled to the complement bitline;
a first complement section switch coupled to a complement plateline and a second end of the first complement memory group, the first complement section switch selectively coupling the first complement memory group to the complement plateline;
a second complement memory group having its first end coupled to the complement bitline; and
a second complement section switch coupled to the complement plateline and a second end of the first complement memory group, the first complement section switch selectively coupling the first complement memory group to the complement plateline.

12. The integrated circuit of claim 11 wherein the first section switch and first complement switch are controlled by a first section selection signal and the second section switch and second complement section switch are controlled by a second selection signal.

13. The integrated circuit of claim 11 wherein the first memory group and first complement memory group are part of a first section of a memory array and the second memory group and second complement memory group are part of a second section of the memory array.

14. The integrated circuit of claim 13 wherein the first complement section switch is activated to couple the first complement memory group to the plateline when the first complement memory group is selected and deactivated to decouple the plateline from the first complement memory group when the first complement memory group is not selected.
